(19) United States
(12) Patent Application Publication
(10) Pub. No.: US 2011/0155061 A1
(43) Pub. Date: Jun. 30, 2011

(54) REACTOR, CHEMICAL VAPOR DEPOSITION REACTOR, AND METALORGANIC CHEMICAL VAPOR DEPOSITION REACTOR

(75) Inventors: Wei-Kuo CHEN, Hsinchu City (TW); Ching-Yu CHEN, Hsinchu City (TW)

(73) Assignee: NATIONAL CHIAO TUNG UNIVERSITY, Hsinchu City (TW)

(21) Appl. No.: 12/945,903

(22) Filed: Nov. 15, 2010

(30) Foreign Application Priority Data
Dec. 31, 2009 (TW) 98146561

(51) Int. Cl. H01L 21/36

(52) U.S. Cl. 118/725

(57) ABSTRACT

A reactor for film deposition having a first heating unit and the second heating units is described. The temperature of each heating unit is controlled individually by heating and/or cooling means. The first heating unit and the second heating unit are disposed face-to-face to each other to form a reaction region therein, and their inner sides are placed with an inclined angle. At least one substrate is disposed on the inner surface of the first heating unit. The temperature of the second heating unit can be adapted to a temperature higher than the temperature of the first heating unit to improve the thermal decomposition efficiency of input reactants so that a low-temperature film deposition can be accomplished.

### RELATED APPLICATIONS

This application claims priority to Taiwan Application Serial Number 98146561, filed Dec. 31, 2009, which is herein incorporated by reference.

### FIELD OF THE INVENTION

The present invention relates to a reactor having a plurality of individual heating units, particularly to a chemical vapor deposition (CVD) reactor having a plurality of individual heating units, and more particularly to a metalorganic chemical vapor deposition (MOCVD) reactor.

### BACKGROUND OF THE INVENTION

Currently, III-V group semiconductor materials have been widely used in semiconductor devices, such as light-emitting diodes (LEDs), laser diodes (LDs) and thin film solar cells. In the industries, a chemical vapor deposition (CVD) system, such as a hydride vapor-phase epitaxy (HVPE) system, a chloride vapor-phase epitaxy (CIVPE) system, a metalorganic chemical vapor deposition (MOCVD) system, is typically used to manufacture opto-electronic devices in the areas of infrared, visible and ultraviolet spectral regions. In addition to the III-V group opto-electronic devices, the CVD system is also used to fabricate a silicon/silicon-germanium device consisting of a plurality of layers in the device, such as a metal layer and a dielectric layer, which may be silicon dioxide (SiO₂), silicon nitride (Si₃N₄), silicon oxynitride (SiON), polycrystalline silicon, a tungsten (W) metal layer, a titanium (Ti) metal layer, a copper (Cu) metal layer, an aluminum (Al) metal layer, a titanium nitride (TiN) barrier layer, a tantalum nitride (TaN) barrier layer, a barium strontium titanium oxide (BaSrTiOₓ) high-k material, a fluorine-doped silicon oxide (SiOF) low-k material or a strontium bismuth tantalate (SrBiTaOₓ) ferroelectric material.

Among the aforementioned CVD systems, the MOCVD system is the most commonly used film deposition system for fabricating III-V group optoelectronic devices, such as GaN-based blue and green LEDs containing InₓGa₁₋ₓN in the device structure. By tuning the In composition x, it is known that the bandgap energy can be varied from 3.4 to 0.7 eV, which corresponding to the emission wavelength from 365 to 1770 nm, covering wide spectral range from ultraviolet, visible to infrared regions. In these devices, a homostructure, a single heterostructure, a double heterostructure, a single quantum well structure, a multiple quantum well or a multiple quantum well imbedded with quantum dots, which are composed of different InₓGa₁₋ₓN constituents, is often used as device structure. The recent development of high power LEDs and solid-state lighting have further attracted attentions on the study of visible LEDs using thick InGaN double heterostructure as light emitting layer, because the increased thickness of the light emitting layer can provide high current and high power operations, which becomes of particular importance for fabrication of high luminous solid state light bulb.

However, the growth of the high In content InGaN thick films with emission wavelengths in the spectral range between green and red colors by using MOCVD method remains challenges at present. The reactants that generally used in MOCVD to grow InGaN film are trimethylgallium (TMGa), trimethylindium (TMIn) and gaseous ammonia (NH₃). Due to the characteristics of different degree of thermal dissociation of the different InₓGa₁₋N film and the poor decomposition efficiency of NH₃, the MOCVD growths of the above InGaN films are required to perform at different temperatures, spanning from 550 to 1200° C., dependent on In composition x. For instance, owing to the high thermal stability nature of material itself, the GaN film is generally grown at a high growth temperature, such as 950° C. or higher so as to obtain better film quality, which can be attributable primarily to the increased supply of active nitrogen atoms due to an improved NH₃ decomposition efficiency at high temperatures. On the contrary, the InN is a thermodynamically unstable material. It has been reported that in a vacuum ambient the InN film starts to decompose at 435° C. and is completely decomposed at 627° C. As a consequence, the MOCVD growth of the InN film is constrained to a temperature range between 550 and 650° C., much lower than that of GaN. Unfortunately, the NH₃ decomposition efficiency in this temperature range is considerably low; only about 4% of NH₃ is decomposed, which suggests even few active nitrogen atoms that can participate in the deposition reaction. The InN film grown under such circumstances will certainly lead to generations of large numbers of native defects to degrade the crystalline quality. In case of the ternary InₓGa₁₋ₓN compounds, their MOCVD growth temperatures lie between those of GaN and InN. Typically, the growth temperatures of InGaN films with low-In contents (5-25%) are comparatively higher, lying in the range of 700-800° C. For those InGaN films with In content >30%, the growth temperatures are required to be reduced further to 550-650° C. in order to suppress the desorption of In atoms from the growing layer. By reducing growth temperature, the entire composition range of InGaN films have been demonstrated to be able being synthesized by using MOCVD growth technique; nevertheless, not all of them possess acceptable optical quality for device fabrication, particularly for In compositions in the range of 40-70%, where no luminescence has yet been reported. The absence of optical signals in the middle composition region of InGaN layers by MOCVD seems to suggest that the strong solid immiscible property originating from the large difference in interatomic spacing between GaN and InN alloys may play an important role in determining the film quality as well, in addition to the aforementioned growth factors: InN thermal instability and inefficient decomposition of NH₃ reactants. All of the above arguments undoubtedly lead to complex combination effects on t MOCVD InGaN growth, giving rise to the presence of large numbers of crystalline defects such as threading dislocations, stacking defaults, nitrogen and In vacancies, and Ga antisites in InGaN films.

In order to enhance the decomposition efficiency of NH₃, especially under low growth temperature environment, many auxiliary methods, such as plasma-, laser-, thermal- and/or ultraviolet irradiation-assisted methods, are developed in the current CVD systems.

The apparatus described in the U.S. Patent Publication No. 2006/0121193 A1 includes a pretreatment apparatus disposed in front of a chamber to facilitate the decomposition of the reactive gas. The pretreatment apparatus includes a plasma generator, a catalytic device or a combination of the aforementioned devices. Parts of source precursors are impinged by high-energy plasma to improve their decomposition efficiencies before entering into the deposition zone to react with other reactants.

The papers in Current Applied Physics 3 351 (2003), and J. Cryst. Growth 247 55 (2003) propose an alternative method by placing a preheating device directly on group V gasline in front of the growth chamber to enhance the decomposition rate of group V precursors. The active reactants that decomposed efficiently in the cracking zone then have to transport to the deposition zone; such a transfer would inevitably cool down the reactant sources again and lead to a decrease of the activity of the reactants.

Therefore, the above reactors, in spite of their specific design features, have not yet demonstrated themselves to be capable of growing material with quality good enough to compete with the current contender, the conventional MOCVD system. For conventional MOCVD reactor that has one single heating unit, also called a susceptor heated by given heating methods, the heating unit not only provides the growth temperature needed for film deposition, but also acts as a cracking device to thermally decompose source precursors. For instance, the MOCVD growth of GaN, because of its highly thermal stability feature due to strong chemical bond between Ga and N atoms, is normally conducted at temperatures higher than 950° C. to obtain high crystalline quality by taking advantages of the improved NH₃ cracking efficiencies at high growth temperatures [Jpn. J. Appl. Phys. 36 L598 (1997)]. With regard to the blue- (450 nm) and green- (520 nm) InGaN materials, the corresponding indium compositions are about 19%, and 25%, respectively. The longer the emission wavelength, the higher the In composition is in the film. However, due to the conflicting temperature requirement imposed by NH₃ cracking efficiency and InN dissociation the growth of InGaN alloy is stringently limited in the temperature range of 550-800° C., depending on the In composition. Normally, the InGaN thick films with In composition <30% are conducted at temperatures >700° C., which exhibit characteristics of better film quality primarily because of enhancement of active N supply due to the improved cracking efficiency at high temperatures. In spite of this, the preparation of higher In content InGaN films in this temperature region remains a great challenge for MOCVD grower, which can be attributable largely to the high desorption rate of In atoms in the employed growth environment that limits the maximum In atoms attainable in the solid. On the other hand, when the growth temperature is reduced to below 700° C., the In composition in InGaN can be increased as anticipated, favoring from the declining In desorption rate; however, the film quality becomes rather poor. This is ascribed to the generation of large density of native defects, such as stacking defaults, nitrogen vacancies, antisites in the film resulted from the shortage supply of active nitrogen atoms as well as the reduced migration capability of surface adatoms. For CVD deposition, unless parasitic reactions are occurred, a higher growth temperature generally gives a better film quality. This is the reason why the blue InGaN thick layer, having lower indium composition (19%), when accomplished at ˜800° C. exhibits a fairly good crystalline quality by using conventional MOCVD method. In case of green InGaN material that having emission wavelength of 520 nm, the call for In composition is ˜25%. To add more In atoms in the solid, the growth temperature has to be reduced accordingly in order to minimize the In desorption effect, which, however, is gained at the expense of film quality. By comparing with the blue light material, the photoluminescence intensity of the green light thick epilayer drops significantly by at least one order of magnitude [J. Crystal Growth. 189 57 (1998)], indicative of a severely deteriorated material quality. This explains for the low internal quantum efficiency of the green light light-emitting diode.

### SUMMARY OF THE INVENTION

In view of the above description related to the prior arts, the single heating unit in conventional reactor plays roles not only cracking the source reactants, but also providing the growth temperature necessitated for film growth. In fact, the temperature requirement between these two functions may conflict with each other, especially under a situation that high decomposition temperature, but low growth temperature is needed for deposition of a specific film, for example, high In-content InGaN material growth. That makes the preparation of such films with high quality extremely difficult.

One objective of the present invention is to provide a reactor for growing a high quality film. The invention disclosed here has the functions that can control independently the thermal decomposition temperature of source precursors and the growth temperature for preparing the thin film, and thereby is capable of promoting the cracking efficiency of source precursors, even pyrolizing completely the source precursors by means of the said second heating unit operating at a high temperature. Therefore, the present invention is able to grow a film with a better film quality at a lower substrate temperature as compared to conventional reactor, especially suitable for preparation of low dissociation temperature material using hardly cracked reactants as source precursors. Nonetheless, this does not exclude the use of the present invention to grow high-quality materials under varieties of growth conditions, including high growth temperature condition.

Another objective of the present invention is to provide a reactor for growing ternary, quaternary compounds or other complex compounds with composition in the middle range, especially for those materials having wide miscibility gap. By using at least two heating units in the reactor, the present invention is able to control independently the thermal decomposition temperature of the source precursors and the film growth temperature so that ternary, quaternary compounds, or other complex compounds can be synthesized in the middle composition region, including those materials having strong solid immiscibility. Still another objective of the present invention is to provide a reactor having a capability of growing electronic, optoelectronic, magnetic devices and etc. at low temperatures. The present invention is feasible to grow semiconductor devices, such as light emitting diodes, laser diodes, photo-detectors, single electron transistors, and magnetic spin transistors at low temperatures, which consist of device structure either a p/n junction, a homostructure, a single heterostructure, a double heterostructure, a single quantum well, or a multiple quantum well structure. Additionally, the reactor of the present invention can be utilized with other advanced process system in varieties of semiconductor industry, including silicon IC industry, to fabricate sophisticated semiconductor devices.

Therefore, an aspect of the present invention is to disclose a reactor for forming a film on at least one substrate. The reactor includes a first heating unit and a second heating unit. The first heating unit and the second heating unit are disposed face to face, and the temperature of the first heating unit and the temperature of the second heating unit can be controlled independently, wherein at least one substrate can be disposed on the surface of the first heating unit located between the first heating unit and the second heating unit. As described earlier, the second heating unit is used to pyrolyze the reactants introduced into the reactor and the first heating unit is used to provide the growth temperature necessitated for film deposition. The deposited film is composed of at least one component in the solid with a specific chemical stoichiometric ratio. Moreover, an inclined angle may be existed between the inner sides of the first heating unit and the second heating unit.

The aforementioned substrates can be driven and rotated by, for example, a step motor or a gas-float rotation method. A gap between the first heating unit and the second heating unit can be varied, and the gap is preferably between several micrometers and three hundreds millimeters.

The temperatures of the aforementioned first and second heating units can be heated by using contact heating methods such as thermal resisted heater or by using non-contact heating methods such as electromagnetic-wave induction heater or electromagnetic wave radiation heater. The electromagnetic wave induction heater can be high frequency induction heater, and the electromagnetic-wave radiation heater can be ultraviolet light, visible light, infrared light or far-infrared light heaters, which all do not depart from the spirit and scope of the present invention. The reactor heating units may further be assisted with cooling units such as liquid cooling units or air cooling units, which collaborate with the aforementioned heating units to accurately control the temperatures of the first and second heating units during the deposition process, thereby be able to increase or decrease the temperature difference between the first heating unit and the second heating unit.

The aforementioned substrates may be selected from a group of substrates consisting of glass substrates, gallium nitride substrates, sapphire substrates, silicon carbide substrates, gallium arsenide substrates, indium phosphide substrates, silicon substrates and etc. The reactants for film deposition may be selected from a group of precursor reactants that are composed of elements selected from IA, IIA, IIIB, IVB, VB, VIB, VIIB, VIII, IB, IIB, IIIA, IVA, VA, VIA, VIIA and/or VIIIA groups in the Periodic Table.

The reactants may be introduced into a reaction region through a gap between the first heating unit and the second heating unit for performing deposition. The reactants may also be introduced into a reaction region through a central gas channel and/or a plurality of gas channels that formed in the first heating unit and/or the second heating unit for performing deposition. Alternatively, a portion of the reactants may be introduced into the reaction region through the gas channels in the first heating and/or the second heating unit, and the other portions of the reactants can be introduced into the reaction region through the gap between the first heating unit and the second heating unit to perform the film deposition. The aforementioned means of introducing the reactants do not depart from the spirit and scope of the present invention.

Another aspect of the present invention is to disclose a chemical vapor deposition (CVD) reactor for forming a thin film on at least one substrate, where the reactor includes the aforementioned first and second heating units.

Still another aspect of the present invention is to disclose a metalorganic chemical vapor deposition (MOCVD) reactor for forming a thin film on at least one substrate, where the reactor includes the aforementioned first and second heating units.

Hence, the reactor for film deposition disclosed by the present invention includes the aforementioned first heating unit and the second heating unit, of which the temperatures are controlled independently. The deposited thin film structure may be a single-layered structure or a multi-layered structure, and may be a homostructure, a single heterostructure, a double heterostructure, a multiple quantum well structure, or a nano-scale structure (such as quantum dots). The deposited layer structures or the nano-scale structures are forms of elemental compounds, binary compounds, ternary compounds, quaternary compounds and other complex compounds, designed with different chemical stoichiometric ratios, which are consisted of elements in IA, HA, IIIB, IVB, VB, VIB, VIIB, VIII, IB, JIB, MA, VA, VA, VIA, VIIA and/or VIIIA groups in the Periodic Table.

In case of the conventional reactor equipped with one single heating unit, the heating unit is mainly used to provide the growth temperature required for film deposition, wherein the temperature of the heating unit is also used as the thermal decomposition temperature to decompose the source precursors. Therefore, when the thermal decomposition temperature required by the source precursors is much higher than the thin film deposition temperature, which is normally constrained by the dissociation temperature of film aroused from the thermally unstable property of material, the temperature of the heating unit is forced to be set at a lower temperature, i.e., deposition temperature, in order to avoid or minimize the material dissociation from the surface during the deposition. However, since the temperature of heating unit is too low to pyrolize the source precursors, only parts or a small portions of source precursors are thermally decomposed; that generally results in poor film quality, failing to meet the requirements imposed by most of the electronic and optoelectronic devices.

Hence, the reactor disclosed by the present invention is equipped with two heating units with independent temperature controls, wherein the second heating unit and the first heating unit are disposed face to face to each other, and the temperature of the first heating unit is used as a film deposition temperature, and the temperature of the second heating unit is mainly used as the temperature to thermally decompose source precursors. Therefore, the reactor disclosed by the present invention can be used to grow varieties of high quality films. Since the thermal decomposition temperature of the source precursors and the film growth temperature can be controlled individually, the reactor not only can be used to perform a growth at a high growth temperature with the use of the source precursors that have low decomposition temperature, but also can be used to perform a growth at a low growth temperature that the use the source precursors having high decomposition temperature. Furthermore, due to the use of second heating unit, the reactor disclosed by the present invention can make the thermal decomposition of the precursor reactants more efficiently, thereby be capable of obtaining a high quality thin film at a relatively low growth temperature. Nonetheless, this does not exclude the use of the present invention to grow high-quality materials under varieties of growth conditions, including high growth temperature.

Therefore, the reactors disclosed by the present invention have the features of growing a thin film at a relatively low growth temperature, so that the qualities of opto-electronic devices and electronic devices, such as light emitting diodes (LEDs), laser diodes, photodetectors, solid-state lighting devices and thin film solar cells, and the qualities of integrated circuit devices including Si, SiGe or low temperature polysilicon (LTPS), can be improved.

### BRIEF DESCRIPTION OF THE DRAWINGS

The foregoing aspects and many of the attendant advantages of this invention are more readily appreciated and become better understood by reference to the following detailed description, when taken in conjunction with the accompanying drawings, wherein:

FIG. 1a through FIG. 1c are schematic diagrams, each of which shows a reactor including a plurality of individual heating units in accordance with a plurality of embodiments of the present invention, where the gas channels for source precursors and carrier gases are disposed in the region between the first heating unit and the second heating unit;

FIG. 2a through FIG. 2d are schematic diagrams, each of which shows a reactor including a plurality of individual heating units in accordance with a plurality of embodiments of the present invention, where the first heating unit is placed at the bottom of the reactor and the gas channels for source precursors and carrier gases are disposed directly through either the first heating unit or the second heating unit, schemed with design of one central gas channel or a plurality of gas channels;

FIG. 3a through FIG. 3d are schematic diagrams, each of which shows a reactor including a plurality of individual heating units in accordance with a plurality of embodiments of the present invention, where the first heating unit is placed at the bottom of the reactor and the gas channels for source precursors and carrier gases are disposed through either the first heating unit or the second heating unit, schemed with the design of one central gas channel or a plurality of gas channels;

FIG. 4a through FIG. 4d are schematic diagrams, each of which shows a reactor including a plurality of individual heating units in accordance with a plurality of embodiments of the present invention, where the first heating unit is placed at the bottom of the reactor and the parts of gas channels for source precursors and carrier gases are disposed directly through the first heating unit and parts of gas channels are disposed through the second heating unit, schemed with design of one central gas channel or a plurality of gas channels;

FIG. 5a through FIG. 5d are schematic diagrams, each of which shows a reactor including a plurality of individual heating units in accordance with a plurality of embodiments of the present invention where the first heating unit is placed at the top of the reactor and the parts of gas channels for source precursors and carrier gases are disposed directly through the first heating unit and parts of them are disposed through the second heating unit, schemed with design of one central gas channel or a plurality of gas channels;

FIG. 6 illustrates photoluminescence spectra of (a) a better GaN film and (b) a worse GaN film, taken at a temperature of 14K;

FIG. 7 illustrates the variations of integrated photoluminescence intensities of GaN films as a function of growth temperature grown by the present invention and prior art. The inset shows the resulted PL full-width at half maxima on the growth temperature;

FIG. 8 shows the dependence of emission wavelength on In composition of InGaN films grown by present invention and the prior art; and

FIG. 9 illustrates the variations of integrated PL intensity against emission wavelength for InGaN films grown by the present invention and the prior art. The inset shows the resulted PL full-width at half maxima on emission wavelength.

### DETAILED DESCRIPTION OF THE PREFERRED EMBODIMENT

The present invention discloses a reactor including a plurality of individual heating units for growing a desirable high quality thin film at a predetermined temperature by controlling independently the thermal decomposition temperature of source precursors and the film growth temperature. The spirit of the present invention will be clearly illustrated by reference to the accompanying drawings and the following detailed description. As a person skilled in the art understands the preferred embodiments of the present invention, various changes and modifications can be made within the spirit and scope of the present invention according to the techniques taught by the present invention.

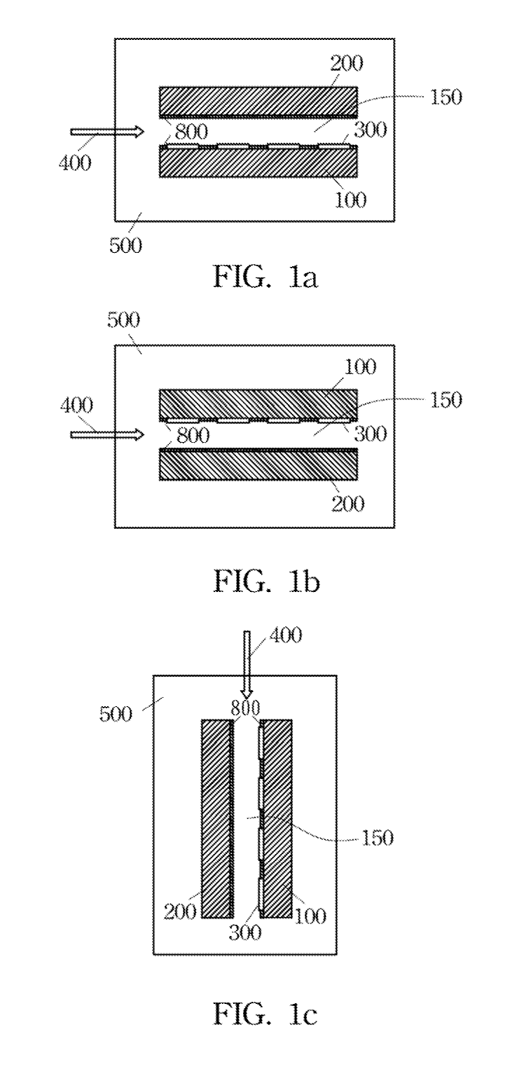

Please refer to FIG. 1a through FIG. 1c, which illustrate a reactor 500, wherein a first heating unit 100 and a second heating unit 200 are disposed inside the reactor 500, thermostated independently at respective predetermined temperatures. The first heating unit 100 and the second heating unit 200 are disposed horizontally, face to face to each other. The embodiment in FIG. 1a shows a reactor with the first heating unit 100 disposed below the second heating unit 200. Alternatively, the first heating unit 100 can also be placed at a position above the second heating unit 200, as shown in FIG. 1b. One or more substrates 300 are disposed on an inner side surface of the first heating unit 100 with good thermal contact. The gap between the first heating unit 100 and the second heating unit 200 is adjustable from several micrometers to three hundreds millimeters, and preferably between 5 and 50 millimeters, and more preferably between 10 and 20 millimeters. The first heating unit 100 and the second heating unit 200 also can be disposed vertically, face to face to each other, as shown in FIG. 1c.

The inner side of the first heating unit 100 is disposed at a predetermined angle with respect to the inner surface of the second heating unit 200, wherein the predetermined angle can be adjusted from, for example, between 0 and 60 degrees, and preferably between 0 and 20 degrees, and more preferably between 0 and 10 degrees. These aforementioned ranges do not depart from the spirit and the scope of the present invention.

During the thin film deposition, a plurality of reactants are introduced by an gas manifold 400 (not drawn in detail in the figure) into the reactor 500 and pass through the gap between the first heating unit 100 and the second heating unit 200 to the reaction region 150. The reactants are flowed over the substrates 300 and preferably flowed over the substrates 300 in a laminar flow manner for performing a reaction, thereby forming films uniformly on surfaces of the substrates 300.

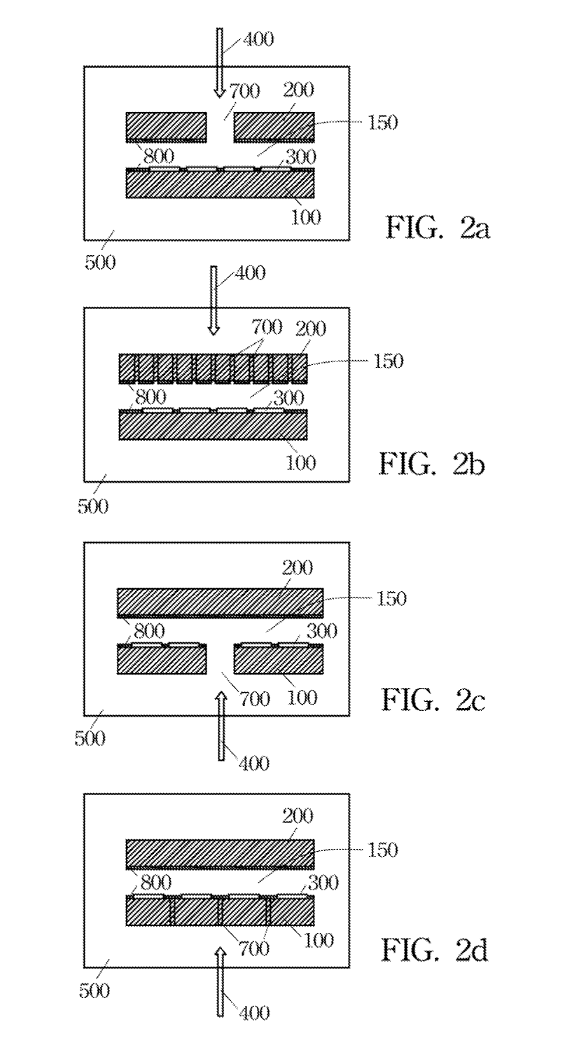

Please refer to the horizontal reactors shown in FIG. 2a through FIG. 2d. Each reactor 500 includes a first heating unit 100 and a second heating unit 200 thermostated independently at respective predetermined temperatures. The first heating unit 100 and the second heating unit 200 are disposed horizontally, face to face to each other. The first heating unit 100 is disposed below the second heating unit 200, and one or more substrates 300 are disposed on an inner side surface of the first heating unit 100 with good thermal contacts. The gap between the first heating unit 100 and the second heating unit 200 is adjustable from several micrometers to three hundreds millimeters, and preferably between 5 and 50 millimeters, and more preferably between 10 and 20 millimeters. The inner side of the first heating unit 100 is disposed at a predetermined angle with respect to the inner side of the second heating unit 200, wherein the predetermined angle can be adjusted, for example, between 0 and 60 degrees, and preferably between 0 and 20 degrees, and more preferably between 0 and 10 degrees. These aforementioned ranges do not depart from the spirit and the scope of the present invention.

At least one of the first heating unit 100 and the second heating unit 200 has one or more gas channels 700 for allowing reactants to enter the reactor 500. The gas channels 700 may be connected to the gas manifold 400 for introducing the reactants and may become a part of structure of the gas manifold 400. Accordingly, the reactants are introduced into the reactor 500 through the manifold 400 and the gas channels 700, and flow into a reaction region 150.

Please refer to the horizontal reactors shown in FIG. 2a through FIG. 2d. Each horizontal reactor includes the underlying first heating unit 100 and the overlying second heating unit 200. In the FIG. 2a and FIG. 2b, the gas channels 700 are disposed in the overlying second heating units 200. The gas channels 700 may include a central gas channel or a plurality of gas channels passing through the second heating unit 200. The reactants can be introduced into the reaction region 150, located between the first heating unit 100 and the second heating unit 200, through completely the gas channels 700 in the second heating unit 200, wherein the gas channels 700 can be in a form of one single central channel (as shown in FIG. 2a), or a plurality of gas channels (as shown in FIG. 2b). The aforementioned reactants then flow over the surfaces of the substrates 300, and preferably flow over the surfaces of the substrates 300 in a laminar flow manner.

Please refer to the horizontal reactors shown in FIG. 2c and FIG. 2d. Each horizontal reactor includes the underlying first heating unit 100 and the overlying second heating unit 200. In the FIG. 2c and FIG. 2d, the gas channels 700 are disposed in the underlying first heating units 100. The gas channels 700 may include a central gas channel or a plurality of gas channels passing through the first heating unit 100. The reactants may be introduced into the reaction region 150, located between the first heating unit 100 and the second heating unit 200, through completely the gas channels 700 in the first heating unit 100, wherein the gas channels 700 can be in a form of one single central channel (as shown in FIG. 2c), or a plurality of gas channels 700 (as shown in FIG. 2d). The aforementioned reactants then flowed over the surfaces of the substrates 300, and preferably flow over the surfaces of the substrates 300 in a laminar flow manner.

Please refer to the horizontal reactors shown in FIG. 2a through FIG. 2d. In order to minimize gas vortex effects on film deposition, the substrates 300 that placed on the inner side surface of the first heating unit 100 are disposed at a distance from the outlets of gas channels, such that the reactants that flow over the surfaces of the substrates 300 are ensured to be a laminar flow manner or nearly a laminar flow manner. Each of the gas channels in the gas channels 700 shown in the figures may further consist of a plurality of micro-channels, a porous channel. However, the figures of the present invention are merely illustrated symbolically, and the structure of the gas channels 700 can be designed according to actual needs, and does not depart from, the spirit and the scope of the present invention.

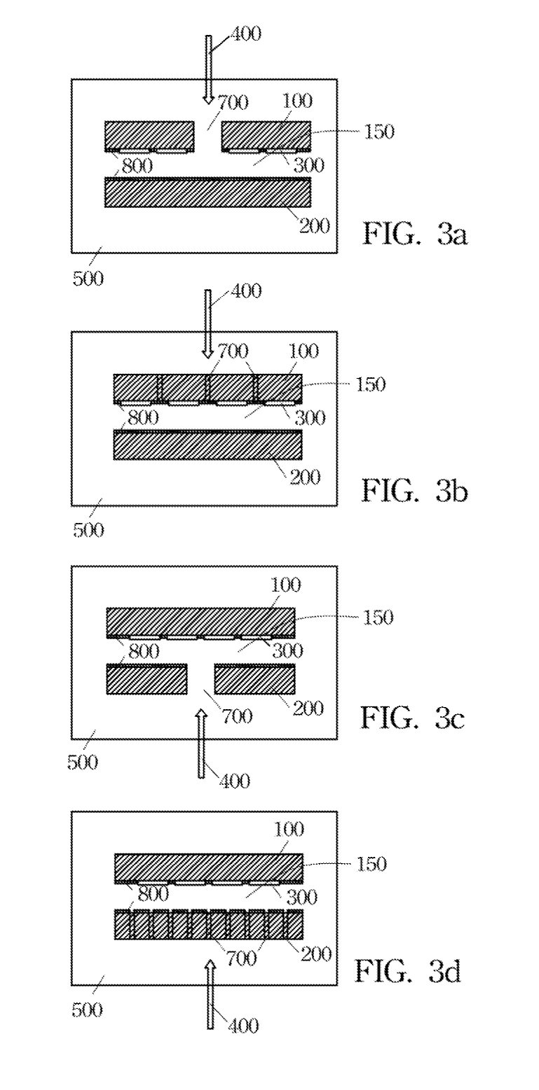

Please to refer to the horizontal reactor shown in FIG. 3a through FIG. 3d. Each reactor 500 includes a first heating unit 100 and a second heating unit 200 thermostated independently at respective predetermined temperatures. The first heating unit 100 and the second heating unit 200 are disposed horizontally, face to face to each other. The first heating unit 100 is disposed above the second heating unit 200, and one or more substrates 300 are disposed on an inner side surface of the first heating unit 100 with good thermal contacts. The gap between the first heating unit 100 and the second heating unit 200 is adjustable from several micrometers to three hundreds millimeters, and preferably between 5 and 50 millimeters, and a more preferably between 10 and 20 millimeters. The inner side of the first heating unit 100 may be disposed at a predetermined angle with respect to the inner side of the second heating unit 200, wherein the predetermined angle can be adjusted, for example, between 0 and 60 degrees, and preferably between 0 and 20 degrees, and more preferably between 0 and 10 degrees. These aforementioned ranges do not depart from the spirit and the scope of the present invention.

At least one of the first heating unit 100 and the second heating unit 200 has one or more gas channels 700 for allowing reactants to enter the reactor 500. The gas channels 700 may be connected to the gas manifold 400 for introducing the reactants and may become a part of structure of the gas manifold 400. Accordingly, the reactants are introduced into the reactor 500 through the manifold 400 and the gas channels 700, and flow into a reaction region 150.

Please refer to the horizontal reactors shown in FIG. 3a through FIG. 3d. Each horizontal reactor includes the overlying first heating unit 100 and the underlying second heating unit 200. In the FIG. 3a and FIG. 3b, the gas channels 700 are disposed in the overlying first heating units 100. The gas channels 700 may include a central gas channel or a plurality of gas channels passing through the first heating unit 100. The reactants can be introduced into the reaction region 150, located between the first heating unit 100 and the second heating unit 200, through completely the gas channels 700 in the first heating unit 100, wherein the gas channels 700 can be in a form of one single central channel (as shown in FIG. 3a), or a plurality of gas channels (as shown in FIG. 3b). The aforementioned reactants then flow over the surfaces of the substrates 300, and preferably flow over the surfaces of the substrates 300 in a laminar flow manner.

Please refer to the horizontal reactors shown in FIG. 3c and FIG. 3d. Each horizontal reactor includes the overlying first heating unit 100 and the underlying second heating unit 200. In the FIG. 3c and FIG. 3d, the gas channels 700 are disposed in the underlying second heating units 200. The gas channel 700 may include a central gas channel or a plurality of gas channels passing through the second heating unit 200. The reactants can be introduced into the reaction region 150, located between the first heating unit 100 and the second heating unit 200, through completely the gas channels 700 in the second heating unit 200, wherein the gas channels 700 can be in a form of one single central channel (as shown in FIG. 3c), or a plurality of gas channels (as shown in FIG. 3d). The aforementioned reactants the flow over the surfaces of the substrates 300, and preferably flow over the surfaces of the substrates 300 in a laminar flow manner.

Please refer to the horizontal reactors shown in FIG. 3a through FIG. 3d. In order to minimize gas vortex effects on film deposition, the substrates 300 that placed on the inner side surface of the first heating unit 100 are disposed at a distance from the outlets of gas channels, such that the reactants that flow over the surfaces of the substrates 300 are ensured to a laminar flow manner or nearly a laminar flow manner. Each of the gas channels in the as channels 700 shown in the figures may further consist of a plurality of micro-channels, or a porous channel. However, the figures of the present invention are merely illustrated symbolically, and the structure of the gas channels 700 can be designed according to actual needs and does not depart from the spirit and the scope of the present invention.

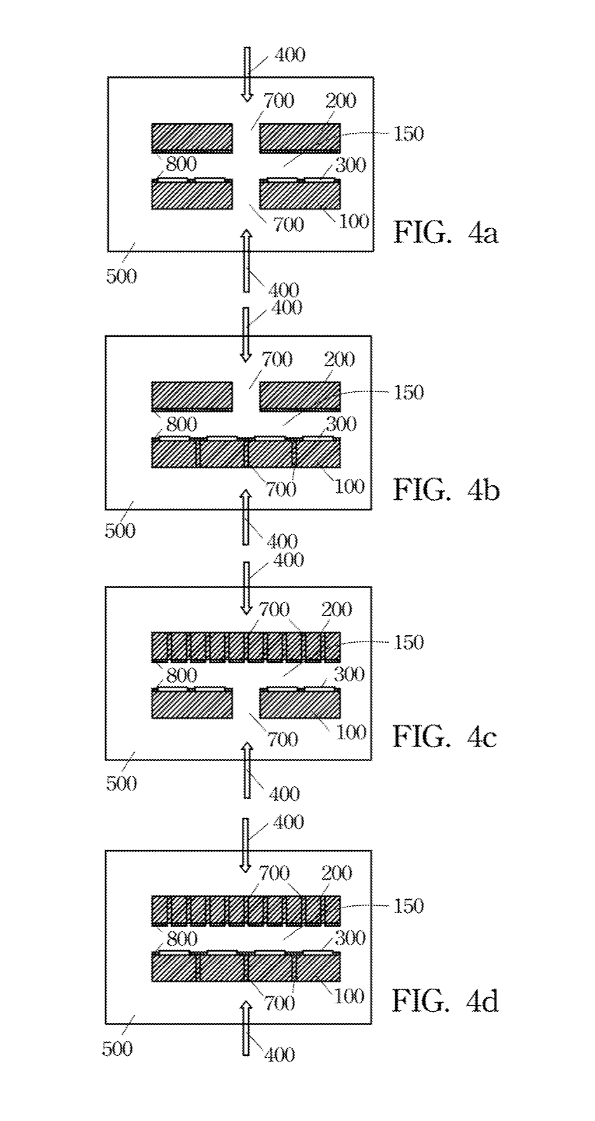

Please refer to the horizontal reactors shown in FIG. 4a through FIG. 4d. Each reactor 500 includes a first heating unit 100 and a second heating unit 200 thermostated independently at respective predetermined temperatures. The first heating unit 100 and the second heating unit 200 are disposed horizontally, face to face to each other. The first heating unit 100 is disposed below the second heating unit 200, and one or more substrates 300 are disposed on the inner side surface of the first heating unit 100 with good thermal contacts. The gap between the first heating unit 100 and the second heating unit 200 is adjustable from several micrometers to three hundreds millimeters, and preferably between 5 and 50 millimeters, and more preferably between 10 and 20 millimeters. The inner side of the first heating unit 100 may be disposed at a predetermined angle with respect to the inner side of the second heating unit 200, wherein the predetermined angle can be adjusted, for example, between 0 and 60 degrees, and preferably between 0 and 20 degrees, and more preferably between 0 and 10 degrees. These aforementioned ranges do not depart from the spirit and the scope of the present invention.

Both of the first heating unit 100 and the second heating unit 200 have one or more gas channels 700 for allowing reactants to enter the reactor 500. The gas channels 700 may be connected to the gas manifold 400 and may become a part of the gas manifold 400. According, the reactants are introduced into the reactor 500 through the gas channels 700 and flow into a reaction region 150.

Please refer to the horizontal reactors shown in FIG. 4a through FIG. 4d. Each horizontal reactor includes the underlying first heating unit 100 and the overlying second heating unit 200. Each heating unit further includes gas channels 700, wherein the gas channels 700 may be in a form of single central gas channel or a plurality of gas channels.

Referring to FIG. 4a and FIG. 4b, a portion of the reactants may be introduced into the reaction region 150, located between the first heating unit 100 and the second heating unit 200, through the gas channels 700 in the second heating unit 200 which is in a form of single central channel, and the other portion of the reactants may be introduced into the reaction region 150 through the gas channels 700 in the first heating unit 100, either in a form of single central channel (as shown in FIG. 4a) or in a form of a plurality of gas channels (as shown in FIG. 4b). The aforementioned reactants then flow over the surfaces of the substrates 300, and preferably flow over the surfaces of the substrates 300 in a laminar flow manner.

Referring to FIG. 4c and FIG. 4d, a portion of the reactants may be introduced into the reaction region 150, located between the first heating unit 100 and the second heating unit 200, through the gas channels 700 in the second heating unit 200 which is in the form of a plurality of gas channels, and the other portion of the reactants may be introduced into the reaction region 150 through the gas channels 700 in the first heating unit 100, wherein the gas channels 700 are either in a form of single central channel (as shown in FIG. 4c) or in a form of a plurality of gas channels (as shown in FIG. 4d). The aforementioned reactants then flow over the surfaces of the substrates 300, and preferably flow over the surfaces of the substrates 300 in a laminar flow manner.

Please refer to the horizontal reactors shown in FIG. 4a through FIG. 4d. In order to minimize gas vortex effects on film deposition, the substrates 300 that placed on the inner side surface of the first heating unit 100 are disposed at a distance from the outlets of gas channels, such that the reactants that flow over the surfaces of the substrates 300 are ensured to a laminar flow manner or nearly a laminar flow manner. Each of the gas channels in the gas channel 700 shown in the figures may further consist of a plurality of micro-channels, or a porous channel. However, the figures of the present invention are merely illustrated symbolically, and the structure of the gas channels 700 can be designed according to actual needs and do not depart from the spirit and the scope of the present invention.

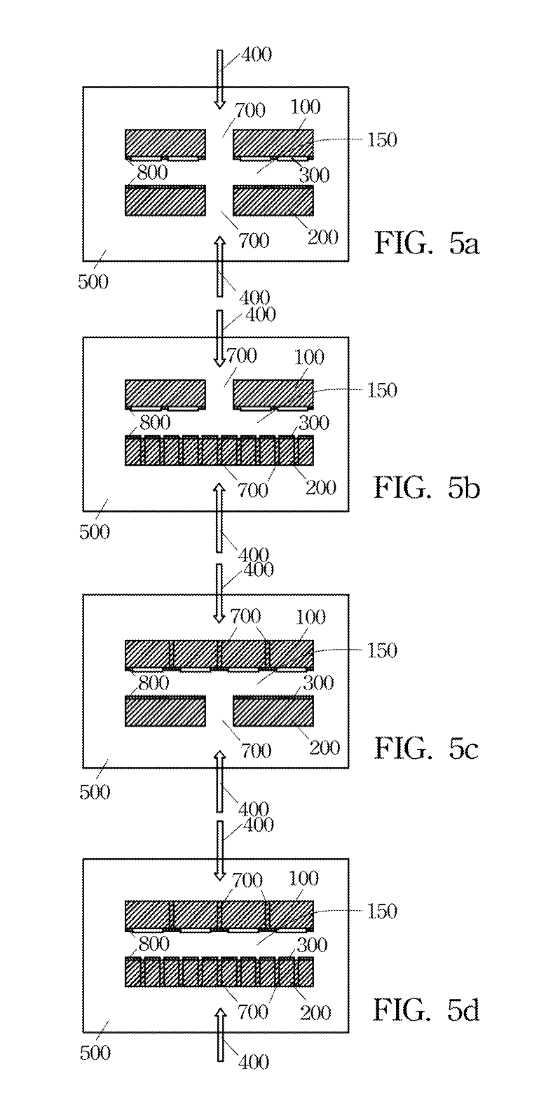

Please refer to the horizontal reactors FIG. 5a through FIG. 5d. Each reactor 500 includes a first heating unit 100 and a second heating unit 200 thermostated independently at respective predetermined temperatures. The first heating unit 100 and the second heating unit 200 are disposed horizontally, face to face to each other. The first heating unit 100 is disposed above the second heating unit 200, and one or more substrates 300 are disposed on the inner side surface of the first heating unit 100 with good thermal contacts. The gap between the first heating unit 100 and the second heating unit 200 is adjustable from several micrometers to three hundreds millimeters, and preferably between 5 and 50 millimeters, and more preferably between 10 and 20 millimeters. The inner side of the first heating unit 100 may be disposed at a predetermined angle with respect to the inner side of the second heating unit 200, wherein the predetermined angle can be adjusted, for example, between 0 and 60 degrees, and preferably between 0 and 20 degrees, and more preferably between 0 and 10 degrees. These aforementioned ranges do not depart from the spirit and the scope of the present invention.

Both of the first heating unit 100 and the second heating unit 200 have one or more gas channels 700 for allowing reactants to enter the reactor 500. The gas channels 700 may be connected to the gas manifold 400 and may become a part of the gas manifold 400. The reactants are introduced into the reactor 500 through the gas channels 700 and flow into the reaction region 150.

Please refer to the horizontal reactors shown in FIG. 5a through FIG. 5d. Each horizontal reactor includes the underlying first heating unit 100 and the overlying second heating unit 200. Each heating unit further includes gas channels 700, wherein the gas channels 700 may be in a form of single central gas channel or a plurality of gas channels.

Referring to FIG. 5a and FIG. 5b, a portion of the reactants may be introduced into the reaction region 150, located between the first heating unit 100 and the second heating unit 200 through the gas channels 700 in the first heating unit 100, which is in a form of single central channel, and the other portion of the reactants may be introduced into the reaction region 150 through the gas channels 700 in the second heating unit 200, wherein the gas channels 700 are in a forms of either single central channel (as shown in FIG. 5a) or a plurality of gas channels (as shown in FIG. 5b). The aforementioned reactants the flow over the surfaces of the substrates 300, and preferably flow over the surfaces of the substrates 300 in a laminar flow manner.

Referring to FIG. 5c and FIG. 5d, a portion of the reactants may be introduced into the reaction region 150, located between the first heating unit 100 and the second heating unit 200, through the gas channels 700 in the first heating unit 100, which is in a form of a plurality of gas channels, and the other portion of the reactants may be introduced into the reaction region 150 through the gas channels 700 in the second heating unit 200, wherein the gas channel 700 are in a forms of either single central channel (as shown in FIG. 5c) or a plurality of gas channels (as shown in FIG. 5d). The aforementioned reactants then flow over the surfaces of the substrates 300, and preferably flow over the surfaces of the substrates 300 in a laminar flow manner.

Please refer to the horizontal reactors shown in FIG. 5a through FIG. 5d. In order to minimize gas vortex effects on film deposition, the substrates 300 that placed on the inner side surface of the first heating unit 100 are disposed at a distance from the outlets of gas channels, such that the reactants that flow over the surfaces of the substrates 300 are ensured to be a laminar flow manner or nearly a laminar flow manner. Each of the gas channels in the gas channels 700 shown in the figures may further consist of a plurality of micro-channels, or a porous channel. The figures of the present invention are merely illustrated symbolically, and the structure of the gas channel 700 can be designed according to actual needs and do not depart from the spirit and the scope of the present invention.

Referring to the reactors shown in FIG. 5a through FIG. 5d, a portion of the reactants may be introduced into the reaction region 150 through the central channel or a plurality of gas channels in the first heating unit 100, another portion of the reactants may be introduced through the central channel or a plurality of gas channels of the second heating unit 200, and the remaining portion of the reactants may be introduced through the gap between the first heating unit 100 and the second heating unit 200. The aforementioned reactants then flow over the surfaces of the substrates 300, and preferably flow over the surfaces of the substrates 300 in a laminar flow manner. The figures of the present invention are merely illustrated symbolically, and the structure of the gas channel 700 can be designed according to actual needs and do not depart from the spirit and the scope of the present invention.

To sum up, in the aforementioned reactors of the present invention, the reactants can be introduced into the reaction region 150, located between the first heating unit 100 and the second heating unit 200, either completely through the central channel or a plurality of gas channels 700 in the first heating unit 100, completely through the central channel or a plurality of gas channels 700 in the second heating unit 200, or completely through the gap between the first heating unit 100 and the second heating unit 200. The reactants further can be introduced into the reaction region 150 partly through the gas channels 700 in the first heating unit 100, partly through the gas channels 700 in the second heating unit 200 and partly through the gap between the first heating unit 100 and the second heating unit 200. At least one of the gas channels in the gas channels 700 may further includes a plurality of micro-channels to allow different reactants flow separately through different micro-channels in order to avoid any parasitic effects that might be occurred between different reactants. The figures of the present invention are merely illustrated symbolically, and the structure of the gas channel 700 can be designed according to actual needs and do not depart from the spirit and the scope of the present invention.

As illustrated in FIG. 1a through FIG. 1c, FIG. 2a through FIG. 2d, FIG. 3a through FIG. 3d, FIG. 4a through FIG. 4d and FIG. 5a through FIG. 5d, the desired temperature of each heating unit can be controlled individually and independently. The first heating unit 100 and the second heating unit 200 can be heated by using contact heating methods, such as thermal resistance wire electric heating, or non-contact heating methods, such as electromagnetic-wave induction heating or electromagnetic-wave radiation heating. Preferably, the above temperature control may be further assisted with cooling units, such as liquid cooling units or air cooling units, in order to increase the temperature difference between the first and second heating units, thereby be able to conduct the high quality film deposition that is required to be conducted at a relatively low growth temperature and relatively high decomposition temperature because of the property of low dissociation temperature of the deposited material itself and use of highly thermally stable source precursors. However, this does not exclude the use of the prevent invention to grow high quality thin film under varieties of growth conditions, including high growth temperature. Furthermore, the first heating unit 100 may include a plurality of heating zones, and the temperatures of heating zones can be controlled individually or inter-correlatively. The second heating unit 200 may also include a plurality of heating zones, and the temperatures of the heating zones may be controlled individually or correlatively. These heating unit structures can be designed according to actual needs and do not depart from the spirit and the scope of the present invention.

Additionally, a protective plate structure 800 may be placed on the inner side surfaces or entire surfaces of the first heating unit 100 and the second heating unit 200 to avoid direct contacts with reaction gases and thereby prolong the lifetime of the heating units. Good thermal contacts are exhibited between the heating units and the protective plate structure 800 in order to provide accurate temperatures that needed for thin film growth. The protective plate structure 800 is preferably made from materials which do not react with the reactants harshly, such as quartz glass, sapphire, platinum and molybdenum. A more preferable material of the protective plate structure may be a low emissivity material to decrease the thermal radiation effect between the above heating units. Preferably, the protective plate structure 800 is replaceable. The protective plate structure 800 can be replaced from time to time so as to keep the deposits thereon within a permissible thickness. The protective plate structure 800 can be designed according to actual needs and do not depart from the spirit and the scope of the present invention.

Moreover, in the present invented reactor 500 the reactants can be introduced into the reaction region 150 through the gas manifold 400 and gas channels 700 from the overlying, underlying heating units or the from side of the reactor, which then flow uniformly over the surfaces of the substrates and form a desirable film thereon.

In the conventional MOCVD epitaxy system with one single heating unit, the heating unit is used mainly to provide the growth temperature needed for thin film deposition, not designed especially for the use of cracking source precursors efficiently. In contrast, in the present invention the reactor is equipped with at least two individual heating units, wherein the first heating unit is used to provide the growth temperature required for film deposition, and the second heating unit is used to provide a temperature, normally higher than the growth temperature, to enhance the decomposition efficiency of source precursors or even to pyrolize completely the source precursors such that a good quality film can be accomplished at a low growth temperature.

### Embodiments of the Growth of a GaN Bulk

FIG. 6 illustrates photoluminescence spectra of GaN epilayers measured at a temperature of 14K. FIG. 6 (a) displays a typical spectrum of high optical quality GaN film grown on a sapphire substrate, where only a narrow near-band emission (NBE) peak, located at 3.40 eV (365 nm), is attained. Since the GaN film is commonly grown on a foreign substrate, most frequently on a sapphire substrate, the large lattice mismatch between GaN and sapphire substrate, ˜16%, is occurred. Under such a circumstance, deteriorated optical properties of the film are often resulted if the growth parameters are not carefully optimized, for example, at a growth temperature of 850° C., which is considerably lower than the optimum growth temperature ˜1100° C. The corresponding photoluminescence spectrum is show in FIG. 6(b), where in addition to presence of the weak near-band emission peak, a strong but rather broad yellow emission band, denoted as YL, is appeared. The YL emission is peaked at 2.2 eV with a full-width at half maximum of ˜380 meV.

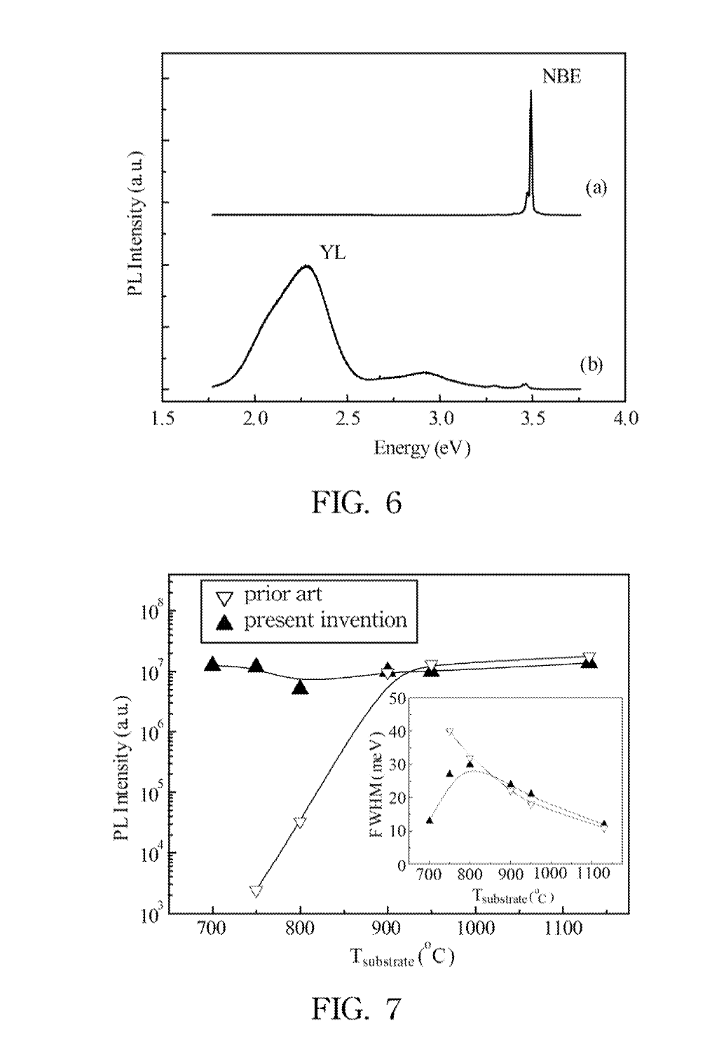

In the first embodiment of the present invention, the photoluminescence spectra of GaN films grown by a conventional MOCVD reactor with single heating unit and the present invented reactor with two individual heating units are used for comparison. Referring to FIG. 7, two series of GaN film were performed by conventional MOCVD reactor and the present invented reactor at growth temperatures from 700 to 1130° C. by using trimethylgallium (TMGa) and ammonia (NH₃) as Ga and N source precursors. The deposition temperature herein is referred to as the temperature of the heating unit in the conventional reactor or the temperature of the first heating unit in the present invention. The major difference between the two series is that except the substrate temperature the present invented reactor provides an additional temperature by the second heating unit, disposed at a position face-to-face to the substrate. Because of the use of hardly decomposed NH₃, the temperature of second heating unit is typically higher than that of the first heating unit (such as from 850° C. to 1130° C.) in order to enhance the thermal decomposition efficiency of the precursor reactants.

In general, the integrated photoluminescence intensity is directly correlated with the photoluminescence efficiency of the optoelectronic material (i.e. the internal quantum efficiency of electrons transforming into photons). The 14 K integrated photoluminescence intensities of the above two series samples as a function of deposition temperature depicted in logarithmic scale are shown in FIG. 7. One can notice that when the deposition temperature is higher than 900° C. the integrated photoluminescence intensities of GaN films, regardless grown by the conventional reactor or the present invention, bear almost the same intensities, nearly independent of growth temperature. On the other hand, when the growth temperature is reduced to below 900° C., notable difference is observed. It can be observed clearly that the photoluminescence intensity of the GaN film grown by the conventional reactor tend to drop considerably with the decreasing growth temperature. For instance, the photoluminescence intensity of 750° C.-sample appears to have an intensity about four-order of magnitude lower than that of 1130° C.-sample and no photoluminescence signal is detectable for film grown at 700° C. by conventional reactor. In contrast, the photoluminescence intensities of the GaN films grown by the present invented reactor do not vary significantly with the growth temperature. The intensity of 700° C. film can still compete with that of high-temperature films.

In addition to the photoluminescence intensity, the resulted full-width at half maximum (FWHM) of the near-band-edge emission is another key parameter to indicate the optical quality of the material. The narrower the FWHM is, the higher the optical quality is resulted. Referring to the inset in FIG. 7, the full-width at half maximum of the near-band-edge emission in the 14 K-spectrum of the GaN film grown at 1130° C. by the prior art is about 11 meV. With the decreasing growth temperature, the FWHM tends to increase gradually. The resulted FWHM reaches 22 meV at 900° C., and ˜40 meV at 750° C. On the other hand, the variation of photoluminescence FWHM of GaN films grown the present invented reactor behaves differently. It increases slowly from 12 to 30 meV as the growth temperature is decreased from 1130° C. to 800° C. Further decrease of the growth temperature, however, does not bring an increase in FWHM value; instead, it drops again. The FWHM is reduced to about 14 meV at 700° C., which can compete to that of the films grown at high temperatures. To our knowledge, this is the best optical quality of low-temperature GaN film ever reported by MOCVD growth method. From the above evidences, it clearly demonstrates that the present invented reactor that having two heating units is able to grow the GaN film at wide growth temperature range, rather than a narrow high temperature growth window imposed by conventional MOCVD reactor due to primarily the reduced cracking efficiency of NH₃. Consequently, a high quality film can be obtained at a lower growth temperature by using the present invented reactor; however, this does not exclude the use of present invented reactor to grow high quality film at a high temperature.

### Embodiments of the Growth of an InGaN Film

Another embodiment of the present invention is used to grow InGaN film. The InGaN is commonly used as an emitting layer in the device structure for GaN-based light emitting devices, which determine the emission wavelength, the most key feature of device specifications. By varying the composition of InGaN emitting layer, we can then adjust the emission wavelength of a light-emitting device from 365 to 1800 nm, spanning widely from ultraviolet to infrared spectral regions. Since the emission wavelength and the interior quantum efficiency of a GaN light-emitting device depend mainly on the material quality of the InGaN emitting layer, the preparation of high quality InGaN film becomes an essential issue for crystal growers during film deposition.

In case of InGaN films grown by conventional MOCVD, their growths are generally divided into three regions: low indium composition region (<40%), high indium composition region (>80%) and middle indium composition region (40-80%). Due to the factors of high volatility of In and the low decomposition of NH₃, high-quality InGaN films with low In contents are normally conducted at high growth temperatures of 700-800° C. As for high In content (>80%) InGaN films, their growths are mandatory to perform at lower temperatures from 550 to 650° C. with the purpose of suppressing the In evaporation from the growing surface and hence increasing the In content in the solid. Despite that the optical signals can be obtained in these samples, their optical quality is far inferior to those low-In content InGaN films, not adequate for device fabrication. The most challenging work for crystal grower using conventional MOCVD reactor is no doubt to grow InGaN films in the middle composition range (40-80%), which is also called highly solid immiscible region. In this region the GaN and InN crystals are generally difficult to mix and crystallize uniformly. Films with this composition range, though, can be still synthesized, as revealed by X-ray measurement, good structure and optical quality InGaN film is hardly achieved. This can be attributable not only to the aforementioned strong solid immiscibility nature associated with the material itself, but also to the properties of the high In violability, the use of hardly decomposed NH₃ source precursor as well as the low surface adatom mobilities during the MOCVD deposition. In fact, up-to-date no optical signal has yet been reported for MOCVD-grown InGaN thick films in the this middle composition range, which corresponding to the emitting wavelengths of 650-1000 nm.

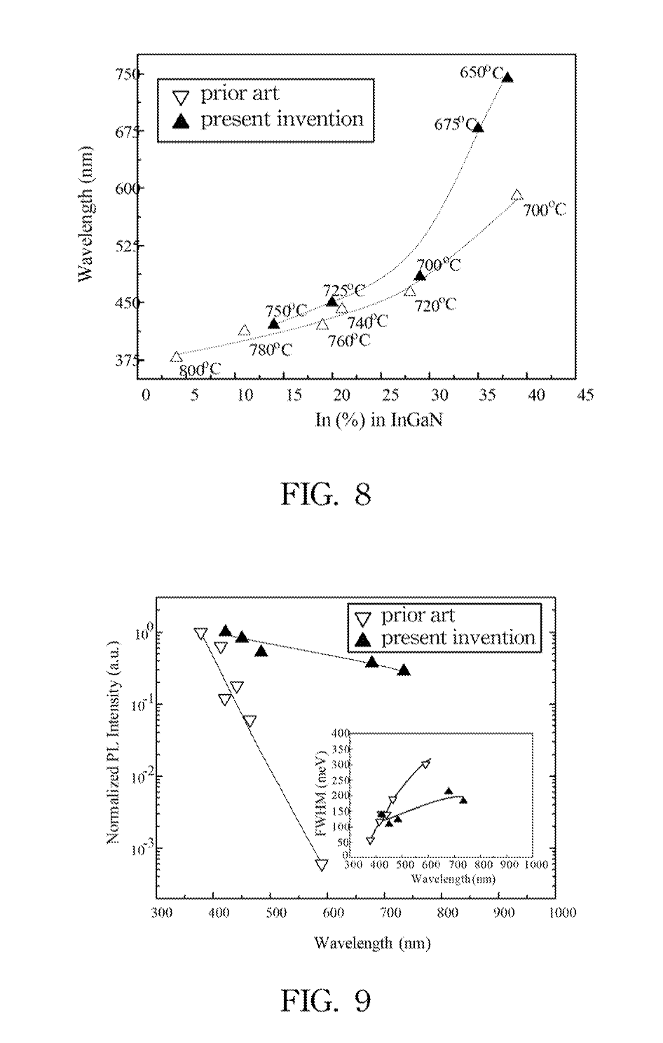

FIG. 8 illustrates the dependence of emission wavelength on the indium composition of MOCVD-grown InGaN films using the present invented MOCVD reactor having two individually controlled heating units. For comparison, the data of InGaN films prepared using the prior art reported from the professor H. X. Jiang in the Kansas University, which is one of the most leading groups in this field, is also illustrated in the figure. The growth temperature is marked intentionally on each sample so that we can envisage the sensitivity of emission wavelength on the growth temperature. The preliminary results show that despite similar InGaN composition range can be accomplished by both the reactors of the prior art and the present invention, longer emission wavelength of the InGaN film can be achieved by using the present invented growth reactor, which can be extended to 680 nm in the red region, even to 740 nm in the near infrared region. To our knowledge, the longest wavelength of the InGaN film in the middle composition region that can be achieved by the prior art is only about 650 nm, much shorter than that by the present invention. Therefore, the wavelength range of the film grown by the reactor of the present invention has surmounted the bottleneck of the prior art in growing good optical quality InGaN film lying in the middle composition region.

In addition to the emission wavelength, the photoluminescence intensity of the film is also one of key parameters relevant to the optoelectronic device quality. FIG. 9 illustrates the dependence of the photoluminescence intensity of above InGaN films on the emission wavelength. As can be seen in the figure, the photoluminescence intensity of InGaN film grown by the prior art drops markedly with the increasing wavelength, attributable primarily to the shortage supply of active N atoms due to poor cracking efficiency of NH₃ reactant under such growth conditions. The photoluminescence intensity of the sample with emission wavelength 590 nm appears to be at least three-order of magnitude lower than that of sample emitting at 370 nm. The remarked drop in photoluminescence intensity with increasing emission wavelength may implicitly explain the reason why no optical signal is ever detected for InGaN film, grown by conventional MOCVD reactor, with emission wavelength longer than 650 nm. On the contrary, by using the present invention equipped with two heating units, the photoluminescence intensity of the InGaN film does not vary substantially. It is worthy to be noted that when the emission wavelength is increased from 420 to 740 nm, the photoluminescence intensity of film is only dropped slightly, by nearly one fifth in magnitude. For comparison, no photoluminescence has ever been reported for InGaN films emitting at wavelengths higher than 650 nm by the prior art.

The variations of FWHMs of 14 K-photoluminescence spectra of above two series of InGaN films are illustrated in the inset of FIG. 9. The FWHM of the InGaN film grown by the prior art appears to rise notably with emission wavelength. The corresponding FWHM value is increased from ˜125 to ˜300 nm as the emission wavelength increases from 420 to 590 nm. On the contrary, a slow variation in FWHM is observed on InGaN films grown by the present invention against the emission wavelength. The FWHM tends to increase from ˜140 to ˜180 nm as the emission wavelength is increased from 420 to 740 nm. The strong photoluminescence signal together with the narrow linewidth observed for 740 nm InGaN sample suggests that the preparation of high optical quality InGaN film in the thermodynamically solid immiscible region is no more an impossible task for MOCVD grower, especially when the present invented reactor is employed.

Therefore, the reactor disclosed by the present invention, equipped with two heating units having individual temperature controls, can deposit a film on a substrate under varieties of growth conditions. The deposited film may consist of either a single-layered structure or a multi-layered structure. The film structure may be a homostructure, a single heterostructure, a double heterostructure, a single quantum well structure, and a multiple quantum well structure, which may also contain nano-scale structures in the layer (such as quantum dots). Each of the deposited layer or the nano-scale structures in the film can be an elemental semiconductor, a binary compound, a ternary compound, a quaternary compound or a more complex compound at a predetermined chemical stoichiometric ratio. The atoms that comprise the aforementioned compound are chosen from the elements in IA, IIA, IIIB, IVB, VB, VIB, VIIB, VIII, IB, IIB, IIIA, IVA, VA, VIA, VIIA and/or VIIIA in the Periodic Table. The deposited layer or nanostructure may be Si, Ge, SiGe, SiC, AlP, AlSb, AlN, GaP, GaAs, GaN, GaS, GaSb, InN, InP, InAs, ZnO, ZnS, ZnSe, ZnTe, CdS, CdSe, CdTe, PbSe, PbTe, CuO, AlGaAs, AlGaN, AlGaP, AlInN, InGaN, InGaAs, GaAsP, GaAlAs, GaAsN, InGaAsP, InAlGaAs, AlGaAsP, AlInGaP or AlGaInN alloy. The deposited film can be further doped with P-type impurities, N-type impurities or iso-electronic dopants, and the type of dopants does not depart from the spirit and the scope of the present invention.

Regarding the reactor having one single heating unit of the prior art, the heating unit temperature is not only used as the growth temperature for film deposition, but is also used as a thermal decomposition temperature to crack the source precursors. When the required thermal decomposition temperature of the source precursors is high, and dissociation temperature of the deposited film is low, large difference in their temperatures is resulted. That makes the crystal grower using the conventional reactor more difficult to select an appropriate temperature for such type of film deposition. Normally, the crystal grower has to select a low growth temperature for film deposition in order to avoid any film dissociation (etching) during sample preparation. However, this usually ends up with a inferior film optical properties because of insufficient supplies of one or more active reactants due to their incomplete decompositions.

Therefore, the reactor disclosed by the present invention has two heating units, wherein the temperature of each unit can be controlled individually. The temperature of the first heating unit is used as a growth temperature of film deposition, and the temperature of the second one is mainly used as the temperature to crack the decompositions of source precursors efficiently. Therefore, the reactor disclosed in the present invention can be used to grow varieties of films with high quality. Since the thermal decomposition temperature of the source precursors and the growth temperature of the film can be controlled individually, the present invented reactor can grow not only a film that has a low reactant thermal decomposition temperature and a high film dissociation temperature, but also a film that has a high reactant thermal decomposition temperature and a low film dissociation temperature. Furthermore, with the second heating unit, the reactor disclosed in the present invention can thermally decompose the precursor reactants more completely, so that a film can be obtained at a lower growth temperature without scarifying the film quality. Accordingly, the reactor disclosed by the present invention can grow a film at a comparatively lower temperature with respective to that of prior art, this could benefit for the fabrications of varieties of opto-electronic devices and electronic devices that prefers the growths of one or more layers in their device structures under lower growth temperatures, such as light emitting diodes (LEDs), laser diodes, photodetectors, solid-state lighting devices, thin film solar cells, and integrated circuit devices containing Si, SiGe or low temperature polysilicon (LTPS) layers.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A reactor used to form a film on at least one substrate, including:
a first heating unit; and
a second heating unit, wherein the first heating unit and the second heating unit are disposed face-to-face to each other to form a reaction region therein; the inner sides of the first heating unit and the second heating unit are placed with an inclined angle, and the temperature of the first heating unit and the temperature of the second heating unit are controlled individually; at least one substrate is disposed on the surface of the first heating unit, located between the first heating unit and the second unit; and a film is formed on at least one substrate disposed on the surface of the first heating unit.

2. The reactor according to claim 1, wherein the inclined angle between the first heating unit and the second unit is adjustable.

3. The reactor according to claim 1, wherein the smallest gap between the first heating unit and the second heating unit is between several micrometers and three hundreds millimeters.

4. The reactor according to claim 1, wherein the first heating unit and the second heating unit are heated by either contact or non-contact means.

5. The reactor according to claim 4, wherein the said reactor further comprises cooling units that work together with the heating units to provide accurate controls of decomposition temperature and deposition temperature; the cooling units are liquid cooling units or air cooling units.

6. The reactor according to claim 1, wherein the first heating unit and the second heating unit are heated by thermal resisted heaters, high frequency induction heaters, ultraviolet lamp heaters, visible lamp heaters and/or infrared lamp heaters.

7. The reactor according to claim 1, wherein at least one substrate is selected from the group of substrates, including glass substrate, gallium nitride substrate, aluminum oxide substrate, silicon carbide substrate, gallium arsenide substrate, indium phosphide substrate and silicon substrate.

8. The reactor according to claim 1, wherein the film is an elemental film or a compound film that composed of two or more elements; wherein the said elements are selected from IA group, IIA group, IIIB group, IVB group, VB group, VIB group, VIIB group, VIII group, IB group, IIB group, IIIA group, IVA group, VA group, VIA group, VILA group and/or VIIIA group in the periodic table.

9. The reactor according to claim 1, wherein the film is further doped with P-type impurities, N-type impurities and/or iso-electronic dopants.

10. The reactor according to claim 1, wherein the at least one substrate is driven rotationally.

11. The reactor according to claim 1, wherein the said first heating unit and second heating unit further include a plurality of heating units; in which the temperatures of the said a plurality of heating units can be controlled individually or inter-correlatively.

12. The reactor according to claim 1, wherein the said reactor further includes a gas manifold to introduce a plurality of reactants into the reactor.

13. The reactor according to claim 1, wherein at least one reactant enter the reaction region through a gap between the first heating unit and the second heating unit.

14. The reactor according to claim 1, wherein at least one of the first heating unit and the second heating unit further includes at least one gas channel formed therein to allow at least one or more reactants to enter into the reaction region.

15. The reactor according to claim 14, wherein at least one gas channel includes a plurality of micro-gas channels to allow the at least a part of the reactants enter separately through the said micro-gas channels into the reaction region.

16. The reactor according to claim 1, wherein the said reactor further includes protection plate structures disposed on the surface of the first heating unit and the surface of the second heating unit to prevent the direct contacts of reactants from the surfaces of the first heating unit and the second heating unit.

17. The reactor according to claim 1, wherein the said reactor is a chemical vapor deposition reactor.

18. The reactor according to claim 1, wherein the said reactor is a metalorganic chemical vapor deposition reactor.

19. The reactor according to claim 1, wherein the film consists of at least one of alloys, including GaN alloy, InN alloy, AlN alloy, GaInN alloy, AlGaN alloy, AlInN alloy, or AlGaInN alloy.
